(19) United States
(12) Patent Application Publication
(10) Pub. No.: US 2014/0099432 A1
(43) Pub. Date: Apr. 10, 2014

(54) FABRICATION METHOD FOR FLEXIBLE CIRCUIT BOARD

(71) Applicant: UNIMICRON TECHNOLOGY CORP., Taoyuan (TW)

(72) Inventors: Tzyy-Jang Tseng, Hsinchu City (TW); Chang-Ming Lee, Taoyuan County (TW); Wen-Fang Liu, Taoyuan County (TW); Cheng-Po Yu, Taoyuan County (TW)

(73) Assignee: UNIMICRON TECHNOLOGY CORP., Taoyuan (TW)

(21) Appl. No.: 13/727,600

(22) Filed: Dec. 27, 2012

(30) Foreign Application Priority Data
Oct. 9, 2012 (TW) 101219568

(51) Int. Cl. H05K 3/00

(52) U.S. Cl. CPC H05K 3/007
USPC 427/97.9; 205/75; 427/98.5

(57) ABSTRACT

A fabrication method for a flexible circuit board is provided. The fabrication method includes the following steps. Firstly, a release film having an upper surface and a lower surface opposite to each other is provided. Next, two flexible substrates are respectively disposed on the upper surface and the lower surface. Next, a plurality of nano-scale micro-pores are formed on each flexible substrate to form two non-smooth flexible substrates. The nano-scale micro-pores evenly distributed over an outer surface of each non-smooth flexible substrate. Each non-smooth flexible substrate being adapted to be performed a plating process directly on the outer surface thereof.

### CROSS-REFERENCE TO RELATED APPLICATION

This application claims the priority benefit of Taiwan application serial no. 101219568, filed on Oct. 9, 2012. The entirety of the above-mentioned patent application is hereby incorporated by reference herein and made a part of this specification.

### BACKGROUND OF THE INVENTION

1. Field of the Invention

The present invention relates to a fabrication method for a flexible circuit board, and more particularly, to a fabrication method for a flexible circuit board having nano-scale rough surface.

2. Description of Related Art

In current information society, people are becoming increasingly dependent on electronic products. To address the demands of high speed, high performance, light-weight, thin and small in size of current electronic products, flexible circuit boards that are bendable have been gradually applied in various electronic devices, such as, mobile phones, notebook PCs, digital cameras, tablet PCs, printers, and disk players.

In general, flexible circuit boards include a polyimide layer. A single surface or two opposite surfaces of the polyimide layer are pre-treated and a sputter process is performed thereon, such that a circuit layer is formed on the single surface or two opposite surfaces of the polyimide layer. However, this fabrication process is complicated. In addition, the sputter process requires a high cost, and polyimide also requires a high cost, which therefore makes the fabrication cost of the flexible circuit boards on the high side.

### SUMMARY OF THE INVENTION

Accordingly, the present invention is directed to a fabrication method for a flexible circuit board which has a simplified fabrication process and a lower fabrication cost.

The present invention provides a fabrication method for a flexible circuit board. The fabrication method includes the following steps. Firstly, a release film having an upper surface and a lower surface opposite to each other is provided. Next, two flexible substrates are respectively disposed on the upper surface and the lower surface. Next, a plurality of nano-scale micro-pores are formed on each flexible substrate to form two non-smooth flexible substrates. The nano-scale micro-pores are evenly distributed over an outer surface of each non-smooth flexible substrate. Each non-smooth flexible substrate is adapted to be performed a plating process directly on the outer surface thereof.

The present invention also provides a fabrication method for a flexible circuit board. The fabrication method includes the following steps. Firstly, a release film having an upper surface and a lower surface opposite to each other is provided. Next, two flexible substrates are respectively disposed on the upper surface and the lower surface. Next, a plurality of openings are formed on each flexible substrate. The openings located on an surface of each flexible substrate. Next, a plurality of nano-scale micro-pores are formed on each flexible substrate to form two non-smooth flexible substrates. The nano-scale micro-pores are evenly distributed over an outer surface of each non-smooth flexible substrates and an inner surface of each opening. Each non-smooth flexible substrate is adapted to be directly performed a plating process on the outer surface and the inner surface.

According to an embodiment of the present invention, the method of forming a plurality of nano-scale micro-pores on each flexible substrate comprises micro-etching process.

According to an embodiment of the present invention, the fabrication method further includes forming two metal layers respectively on the outer surfaces of the non-smooth flexible substrates.

According to an embodiment of the present invention, the method of forming the metal layers respectively on the outer surfaces of the non-smooth flexible substrates comprises electroplating or electroless plating.

According to an embodiment of the present invention, the fabrication method further includes forming a plurality of openings on each of the metal layers. Each of the openings exposes a part of the corresponding outer surface.

According to an embodiment of the present invention, the fabrication method further includes separating the release film from the non-smooth flexible substrates to form the two independent flexible circuit boards.

According to an embodiment of the present invention, each of the non-smooth flexible substrates comprises evenly distributed nano-scale silicon dioxide particles.

According to an embodiment of the present invention, the fabrication method further includes forming a metal layer filled into the openings.

In view of the foregoing, in embodiments of the present invention, each of the flexible substrates having multiple nano-scale micro-pores are disposed on the release film. By taking advantage of the nano-scale rough surfaces of the flexible substrates, the flexible substrates are made suitable for subsequent processes such as electroplating or electroless plating to be directly performed on the flexible substrates to form circuit layers, via holes or embedded circuits, without having to perform a sputter process prior to the plating process. Therefore, embodiments of the present invention can not only simplify the fabrication process of the flexible circuit boards, but also can reduce the cost.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F illustrate the processes of the fabrication method for the flexible circuit board according to one embodiment of the present invention.

FIG. 2A to FIG. 2F illustrate the processes of the fabrication method for the flexible circuit board according to another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

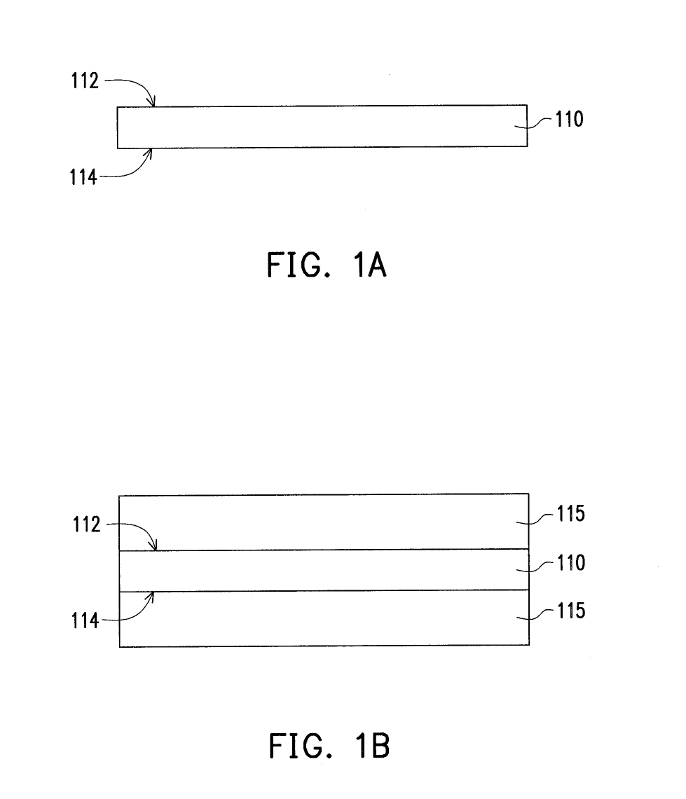

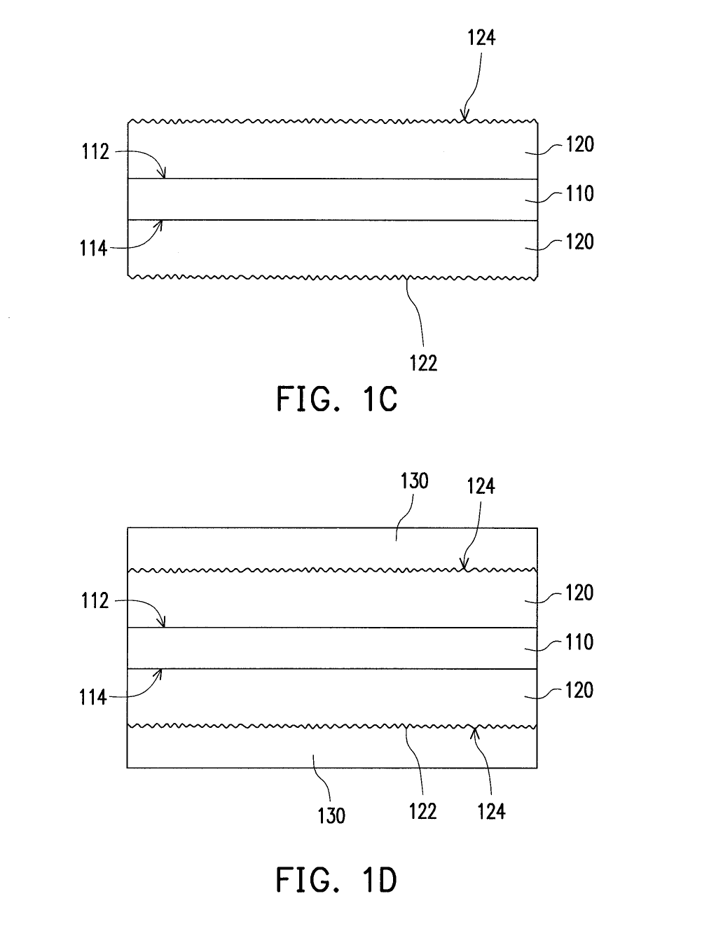

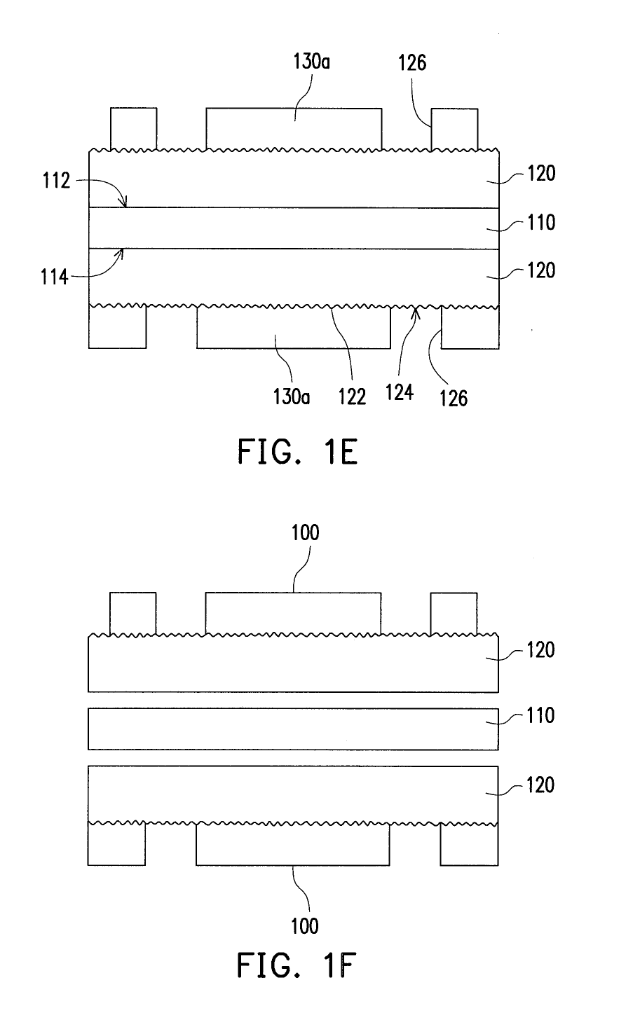

FIG. 1A to FIG. 1F illustrate the processes of the fabrication method for the flexible circuit board according to one embodiment of the present invention. Referring to FIG. 1A, in the present embodiment, the fabrication method for the flexible circuit board includes the following steps. First of all, a release film 110 is provided. The release film 110 includes an upper surface 112 and a lower surface 114 opposite to each other. Next, referring to FIG. 1B, two flexible substrates 115 are respectively disposed on the upper surface 112 and the lower surface 114. Then, referring to FIG. 1C, a plurality of nano-scale micro-pores 122 are formed on each flexible substrate (as the flexible substrates 115 shown in FIG. 1B) to form two non-smooth flexible substrates 120 as shown in FIG. 1C. The nano-scale micro-pores 122 are evenly distributed over an outer surface 124 of each non-smooth flexible substrate 120. In the present embodiment, the nano-scale micro-pores 122 are formed by micro-etching process. As a result, the outer surface 124 of each non-smooth flexible substrate 120 presents a nano-scale rough surface. Because the size of each nano-scale micro-pore is less than 100 nm, the nano-scale rough surface can have good bonding relationship with a metal seed layer which is chemically plated on the outer surface 124 of each non-smooth flexible substrate 120, so that the non-smooth flexible substrates 120 are suitable for electroplating, without having to perform a sputter process prior to the chemical plating or electroplating and then depositing a metal layer on each non-smooth flexible substrate. In the present embodiment, each of the non-smooth flexible substrates 120 includes evenly distributed nano-scale silicon dioxide particles, such that the plurality of nano-scale micro-pores 122 are formed on the outer surface 124 of the substrate 120 by a micro etching process.

Referring to FIG. 1D, in the present embodiment, two metal layers 130 can further be formed respectively on the outer surfaces 124 of the non-smooth flexible substrates 120. In the present embodiment, the metal layers 130 may be formed on the corresponding outer surfaces 124 of the non-smooth flexible substrates 120 by, for example, electroplating or deposition. A material of the metal layer 130 includes, but not limited to, for example, copper, palladium, nickel and etc.

Referring to FIG. 1E, in the present embodiment, a plurality of openings 126 can further be formed on each of the metal layers 130 shown in FIG. 1D to form two patterned metal layers 130a. Each of the openings 120 exposes a part of the corresponding outer surface 124. The openings 126 may be formed by, for example, lithography etching. The patterned metal layers 130a can thus be formed as circuit layers of the non-smooth flexible substrates 220.

Referring to FIG. 1F, in the present embodiment, the material of the release film 110 includes adhesive gel, such as but not limited to, epoxy, polyethylene (PE), polypropylene (PP), etc. The release film 110 is usually a thin film with a surface detachability, which does not exhibit adhesiveness or only exhibits slight adhesiveness under specific condition. In the present embodiment, the non-smooth flexible substrates 120 are disposed on the upper surface 112 and the lower surface 114 of the release film 110, respectively. Therefore, by taking advantage of the characteristic of the release film 110 being easily released from the non-smooth flexible substrates 120, the non-smooth flexible substrates 120 are separated from the release film 110 to form two independent flexible circuit boards 100, as shown in FIG. 1F, the flexible circuit boards is completed.

As constructed above, in the present embodiment, each of the non-smooth flexible substrates 120 with multiple nano-scale micro-pores 122 is disposed on the release film 110. The size of each nano-scale micro-pore is less than 100 nm. Therefore, the nano-scale rough surfaces of the non-smooth flexible substrates 120 can have good bonding relationship with the metal seed layers which are chemically plated on the outer surfaces 124 of the non-smooth flexible substrates 120 respectively, so that the non-smooth flexible substrates 120 are suitable for electroplating, without having to perform a sputter process prior to the chemical plating or electroplating and then depositing a metal layer on each non-smooth flexible substrate. Afterwards, the metal layer 130 may be patterned by lithography process to form a circuit layer of the flexible circuit board. In addition, in the present embodiment, by further taking advantage of the characteristic of the release film 110 being easily released from the non-smooth flexible substrates 120, the non-smooth flexible substrates 120 are separated from the release film 110 after fabrication process of the flexible circuit boards respectively on the upper and lower surfaces of the release film 110 is completed. Therefore, two flexible circuit boards can be fabricated at one time.

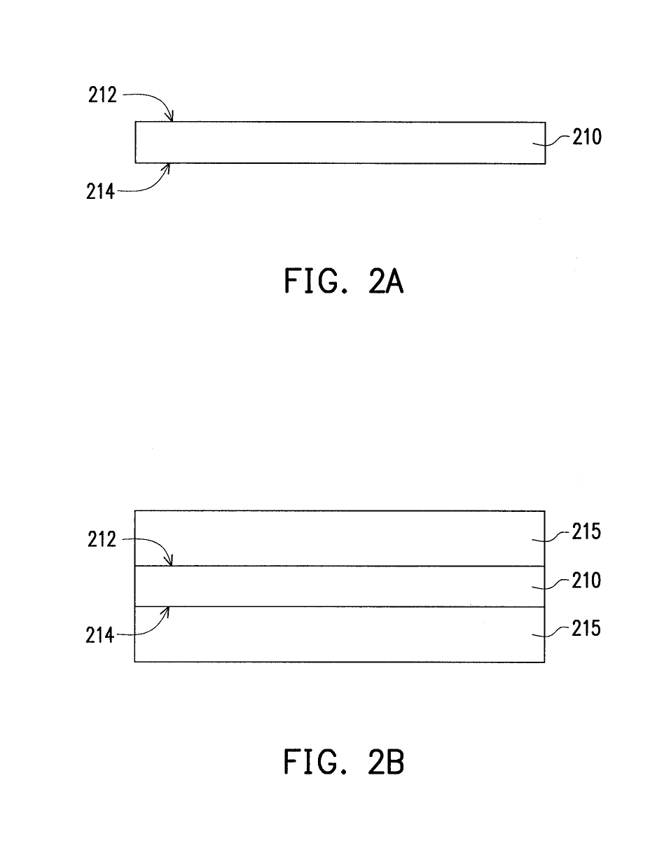

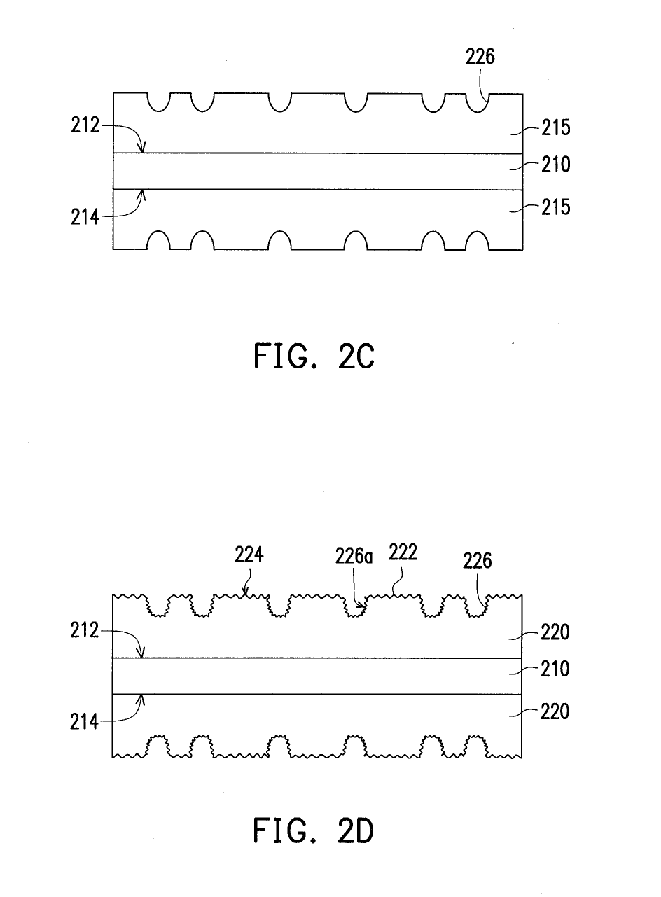

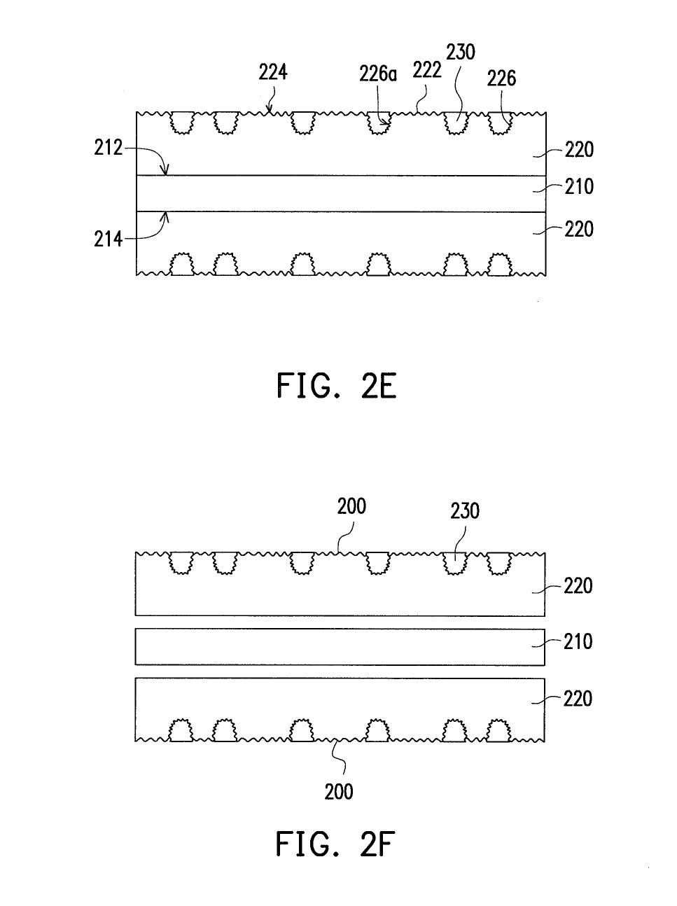

FIG. 2A to FIG. 2F illustrate the processes of the fabrication method for the flexible circuit board according to another embodiment of the present invention. Referring to FIG. 2A, the fabrication method for the flexible circuit board includes the following steps. First of all, a release film 210 is provided. The release film 210 has an upper surface 212 and a lower surface 214 opposite to each other. Next, referring to FIG. 2B, two flexible substrates 215 are disposed on the upper surface 212 and the lower surface 214, respectively. Then, as shown in FIG. 2C, a plurality of openings 226 are formed on each flexible substrate 215. The openings 226 are located on an surface of each non-smooth flexible substrate 215. In the present embodiment, the openings 226 may be formed by, for example, laser-drilling or mechanical drilling.

Next, referring to FIG. 2D, a plurality of nano-scale micro-pores 222 are formed on each flexible substrate as shown in FIG. 2C to form two non-smooth flexible substrates 220 as shown in FIG. 2D. The openings 226 are located on an outer surface 224 of each non-smooth flexible substrate 220, and the nano-scale micro-pores 222 are evenly distributed over each outer surface 224 and over an inner surface 226a of each opening 226. In the present embodiment, each of the non-smooth flexible substrates 220 includes evenly distributed nano-scale silicon dioxide particles, and the plurality of nano-scale micro-pores 222 are formed by micro etching process. As a result, the outer surface 224 of each non-smooth flexible substrate 220 and the inner surfaces 226a of the openings 226 exhibit nano-scale rough surfaces, thereby increasing their bonding ability with the metal seed layers, which makes the non-smooth flexible substrates 220 suitable for electroplating, without having to perform a sputter process prior to the chemical plating or electroplating and then depositing a metal layer on each non-smooth flexible substrate.

Referring to FIG. 2E, in the present embodiment, a metal layer 230 is further formed to be filled in the openings 226. In the present embodiment, a material of the metal layer 230 includes, but not limited to, for example, copper, palladium, nickel, etc. The metal layer 230 may be filled into the openings 226 by, for example, electroplating or deposition. The metal layer 230 can thus be formed as embedded circuits of the non-smooth flexible substrates 220.

Referring to FIG. 2F, in the present embodiment, the non-smooth flexible substrates 220 are respectively disposed on the upper and lower surfaces of the release film 210. By taking advantage of the characteristic of the release film 210 being easily released from the non-smooth flexible substrates 220, the non-smooth flexible substrates 220, as shown in FIG. 2F, can be separated from the release film 210 to form two independent flexible circuit boards 200 after fabrication process of the flexible circuit boards is completed.

In summary, in the present disclosure, the non-smooth flexible substrates having multiple nano-scale micro-pores are disposed on the release film. By taking advantage of the nano-scale rough surfaces of the non-smooth flexible substrates, the non-smooth flexible substrates are made suitable for electroplating, such that subsequent processes such as electroplating or chemical plating can be directly performed on the non-smooth flexible substrates to form circuit layers, via holes or embedded circuits, without having to perform a sputter process prior to the electroplating process. In addition, by taking advantage of the characteristic of the release film being easily released from the non-smooth flexible substrates, the non-smooth flexible substrates are separated from the release film after fabrication process of the flexible circuit boards respectively on both upper and lower surfaces of the release film is completed, which makes it possible to fabricate two flexible circuit boards at one time. Therefore, the present disclosure can not only simplify the fabrication process of the flexible circuit boards, but also can save the cost on the sputter process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

To the claims:

1. A fabrication method for a flexible circuit board, the fabrication method comprising:
providing a release film having an upper surface and a lower surface opposite to each other; and
disposing two flexible substrates respectively on the upper surface and the lower surface;
forming a plurality of nano-scale micro-pores on each flexible substrate to form two non-smooth flexible substrates, the nano-scale micro-pores evenly distributed over an outer surface of each non-smooth flexible substrate;
directly forming two metal layers respectively on the outer surfaces of the non-smooth flexible substrates by electroplating;
forming a plurality of openings on each of the metal layers, each of the openings exposing a part of the corresponding outer surface; and
separating the release film from the non-smooth flexible substrates to form the two independent flexible circuit boards.

2. The fabrication method for the flexible circuit board as claimed in claim 1, wherein the method of forming a plurality of nano-scale micro-pores on each flexible substrate comprises micro-etching process.

3. (canceled)

4. The fabrication method for the flexible circuit board as claimed in claim 1, wherein each of the non-smooth flexible substrates comprises evenly distributed nano-scale silicon dioxide particles.

5. A fabrication method for a flexible circuit board, the fabrication method comprising:
providing a release film having an upper surface and a lower surface opposite to each other;
disposing two flexible substrates respectively on the upper surface and the lower surface;
forming a plurality of openings on each flexible substrate, the openings located on an surface of each flexible substrate;
forming a plurality of nano-scale micro-pores on each flexible substrate to form two non-smooth flexible substrates, the nano-scale micro-pores evenly distributed over an outer surface of each non-smooth flexible substrates and an inner surface of each opening;
directly forming a metal layer filled into the openings by electroplating; and
separating the release film from the non-smooth flexible substrates to form two independent flexible circuit boards.

6. The fabrication method for the flexible circuit board as claimed in claim 5, wherein the method of forming a plurality of nano-scale micro-pores on each flexible substrate comprises micro-etching process.

7. The fabrication method for the flexible circuit board as claimed in claim 5, wherein each of the non-smooth flexible substrates comprises evenly distributed nano-scale silicon dioxide particles.
